(19) United States
(12) Patent Application Publication
(10) Pub. No.: US 2013/0089681 A1
(43) Pub. Date: Apr. 11, 2013

(54) PLASMA-ENHANCED DEPOSITION OF TITANIUM-CONTAINING FILMS FOR VARIOUS APPLICATIONS USING AMIDINATE TITANIUM PRECURSORS

(71) Applicants: Christian Dussarrat, Wilmington, DE (US); Vincent M. Omarjee, Grenoble (FR); Clement Lansalot-Matras, Tsukuba (JP)

(72) Inventors: Christian Dussarrat, Wilmington, DE (US); Vincent M. Omarjee, Grenoble (FR); Clement Lansalot-Matras, Tsukuba (JP)

(73) Assignees: L'Air Liquide Societe Anonyme pour l'Etude et l'Exploitation des Procedes Georges Claude, Paris (FR); American Air Liquide, Inc., Fremont, CA (US)

(21) Appl. No.: 13/269,163

(22) Filed: Oct. 7, 2011

(51) Int. Cl. C23C 16/18

(52) U.S. Cl. 427/576

(57) ABSTRACT

The present invention relates to a process for the use of Titanium amidinate metal precursors for the deposition of Titanium-containing films via Plasma Enhanced Atomic Layer Deposition (PEALD) or Plasma Enhanced Chemical Vapor Deposition (PECVD).

### TECHNICAL FIELD

The present invention relates to a process for the use of metal amidinate metal precursors for the deposition of metal containing film via Plasma Enhanced Atomic Layer Deposition (PEALD) or Plasma Enhanced Chemical Vapor Deposition (PECVD).

### BACKGROUND ART

Refractory metal silicides are attractive for the fabrication of advanced integrated circuits due to their high temperature stability and low electrical resistivity.

These metal silicides have been used as interconnection and gate materials instead of/or in conjunction with polycrystalline silicon to realize faster and smaller devices.

Titanium disilicide can allow low resistivity and low contact resistance.

TiSi2 is prepared using the self-aligned silicide (SALICIDE) process.

The SALICIDE process is based on the solid state reaction of Ti with Si.

Although this reaction is thermodynamically preferable it is a multiple-step difficult process: deposit titanium at the bottom of a high-aspect-ratio contact hole is the main challenge.

In order to improve these drawbacks, ALD or CVD precursor would be needed to improve the process allowing excellent conformal coverage and high throughput.

Titanium metal has always been a great challenge to deposit in ALD.

The only validated process relies on the use of TiCl4 and plasma H2.

However the film was highly oxygen sensitive. (ex: Fouad et al., Journal of Crystal Growth, 234, issue 2-3, 440-446, 2002).

Titanium tris amidinate precursors can be prepared according to the published method in Inorganic Chemistry, Vol. 42, No. 24, 2003 7953 by reacting TiCl3 with tree equivalent of the corresponding lithium amidinate.

### DISCLOSURE OF INVENTION

The invention may be defined in part by the following paragraphs [00014]-[00027]:
A method for depositing a Titanium-containing film comprising the step of providing a Titanium guanidinate and/or Titanium or amidinate precursor, suitable for plasma deposition at temperature equal or lower than 300 degrees C., to a plasma deposition process comprising a deposition temperature equal or lower than 300 degrees C.
The method of paragraph [00014], wherein the deposition temperature is at a temperature of 20-300 degrees C.
The method of paragraph [00014], wherein the deposition temperature is at a temperature of 150-300 degrees C.
The method of any one of paragraphs [00014]-[00016], wherein the Titanium-containing film is deposited on a substrate coated with one or more of Ru, Mn, Low-k, Ta, TaN, SiO₂.
The method of any one of paragraphs [00014]-[00016], further comprising at least a step of providing one co-reactant amine or reducing agent to the plasma deposition process.
The method of any one of paragraphs [00014]-[00016] or any one of paragraphs [00014]-[00016] in combination with one or both of paragraphs [00017] or [00018], further comprising a step of providing one or more of O₂, O₃, H₂O, H₂O₂, NO, NO₂, or a carboxylic acid to the plasma deposition process.
The method of any one of paragraphs [00014]-[00016] or any one of paragraphs [00014]-[00016] in combination with one or more of paragraphs [00017]-[00019], wherein the plasma deposition process is a PECVD process.
The method of paragraph [00018], wherein the plasma deposition process is a PEALD process comprising a plurality of cycle.
The method of any one of paragraphs [00014]-[00016] or any one of paragraphs [00014]-[00016] in combination with one or more of paragraphs [00017]-[00021], wherein the Titanium film is a substantially pure Titanium.
The method of any one of paragraphs [00014]-[00016] or any one of paragraphs [00014]-[00016] in combination with one or more of paragraphs [00017]-[00022], wherein the suitable Titanium precursor has the structure of compound (III)

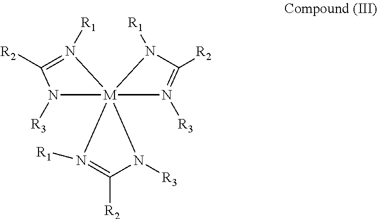

wherein:
M is Ti; and
R₁ and R₃ are independently selected from H, a C1-C5 alkyl group, and Si(R′)₃, where R′ is independently selected from H, and a C1-C5 alkyl group. R₂ is independently selected from H, a C1-C5 alkyl group, and NR′R″, where R′ and R″ are independently selected from C1-C5 alkyl groups.
The method of one of paragraphs [00014]-[00016] or any one of paragraphs [00014]-[00016] in combination with one or more of paragraphs [00017]-[00022] wherein the Titanium precursor is tris(N,N′-diisopropylpentylamidinato)Titanium.

The present invention relates to a process for the use of Titanium amidinate metal precursors for the deposition of Titanium-containing films via Plasma Enhanced Atomic Layer Deposition (PEALD) or Plasma Enhanced Chemical Vapor Deposition (PECVD). Plasma improves deposition rates and/or film properties at deposition temperatures below 300 degrees C. The identification of plasma compatible Titanium amidinate precursors permits the application of plasma to Titanium depositions to derive the benefits of PECVD or PEALD and achieve acceptable deposition rates and film properties at the industrially required temperatures.

In some embodiments, the present invention provides methods of depositing pure Titanium film by plasma enhanced atomic layer deposition (PEALD) and plasma enhanced chemical vapor deposition (PECVD). “Pure Titanium” is defined as at least 90% Titanium such as 95% or more Titanium, 99% or more Titanium or 99.9% or more Titanium.

In some embodiments of the invention, Titanium amidinate or Titanium guanidinate is used at deposition temperatures lower than 300 degrees C. to form Titanium films.

In some embodiments, the Titanium deposition method includes the steps of providing a substrate; providing a vapor of a Titanium guanidinate or a Titanium amidinate precursor; and contacting the vapor including the at least one Titanium precursor with the substrate (and typically directing the vapor to the substrate) to form a Titanium-containing layer on at least one surface of the substrate at temperature of 300 degrees C. or lower.

In some embodiments, the substrate is coated with a surface diffusion or barrier layer. Examples of diffusion layers or glue layers are without limitation TaN, Ta, SiO2, Si, low-k, Mn or any combination thereof.

In one embodiment of the invention, the preferred Titanium precursor is represented by compound (III)

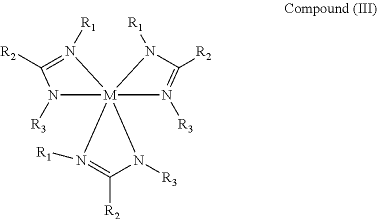

wherein M is Ti; and

R₁ and R₃ are independently selected from H, a C1-C5 alkyl group, and Si(R′)₃, where R′ is independently selected from H, and a C1-C5 alkyl group. R₂ is independently selected from H, a C1-C5 alkyl group, and NR′R″, where R′ and R″ are independently selected from C1-C5 alkyl groups.

An exemplary species of Titanium precursor is tris(N,N′-diisopropylpentylamidinato)Titanium.

Deposition conditions for the invention include temperatures at or below 300 degrees C. preferably in the range of 20-300 degrees C.

Deposition conditions for the invention may also include pressures ranging from 0.5 mTorr to 20 Torr to deposit films having the general formula M, MₖSiₗ, MₙOₘ or MₓN_{y}O_{z}. Film composition will be dependent on the application. Where k, l, m, n, x, y range from 1 to 6, inclusive.

The deposition may include one or more co-reactants such as an amine containing reactant or a reducing agent. Exemplary co-reactants are H₂, NH₃, dimethylsilane, diethylsilane, BuNH₂, B₂H₆, GeH₄, SnH₄, AlH₃, or an alkyl silane containing a Si—H bond.

The deposition may include one or more co-reactant oxygen sources preferably O₂, O₃, H₂O, H₂O₂, NO, NO₂, a carboxylic acid,

The Titanium precursor may be delivered in neat form or in a blend with a suitable solvent, preferably Ethyl benzene, Xylenes, Mesitylene, Decane, or Dodecane in suitable concentrations.

In some embodiments, preferred applications but not limited to could be Titanium deposition on silicon to form a silicide, metal deposition on Ta, TaN or WN to ultimately form metal layer, metal oxide deposition for ReRAM applications.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

What is claimed is:

1. A method for depositing a Titanium-containing film comprising the step of providing a Titanium guanidinate and/or Titanium amidinate precursor, suitable for plasma deposition at temperature equal or lower than 300 degrees C., to a plasma deposition process comprising a deposition temperature equal or lower than 300 degrees C.

2. The method of claim 1, wherein the deposition temperature is at a temperature of 20-300 degrees C.

3. The method of claim 1, wherein the deposition temperature is at a temperature of 150-300 degrees C.

4. The method of claim 1, wherein the Titanium-containing film is deposited on a substrate coated with one or more of Ru, Mn, Low-k, Ta, TaN, or SiO₂.

5. The method of claim 1, comprising a step of providing at least one co-reactant amine or reducing agent to the plasma deposition process.

6. The method of claim 1, further comprising a step of providing to the plasma deposition process one or more of O₂, O₃, H₂O, H₂O₂, NO, NO₂, or a carboxylic acid.

7. The method of claim 1, wherein the plasma deposition process is a PECVD process.

8. The method of claim 7, wherein the plasma deposition process is a PEALD process comprising a plurality of cycle.

9. The method of claim 1, wherein the Titanium film is a substantially pure Titanium.

10. The method of claim 1, wherein the suitable Titanium precursor has the structure of compound (Ill) 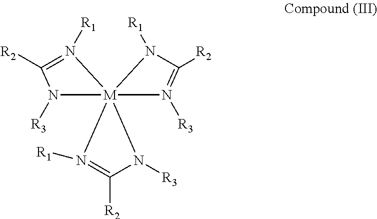
wherein:
M is Ti; and
R₁ and R₃ are independently selected from H, a C1-C5 alkyl group, and Si(R′)₃, where R′ is independently selected from H, and a C1-C5 alkyl group. R₂ is independently selected from H, a C1-C5 alkyl group, and NR′R″, where R′ and R″ are independently selected from C1-C5 alkyl groups.

11. The method of claim 10, where the suitable Titanium precursor is tris(N,N′-diisopropylpentylamidinato)Titanium.
